(19) United States
(12) Patent Application Publication
(10) Pub. No.: US 2010/0255660 A1
(43) Pub. Date: Oct. 7, 2010

(54) SULFURIZATION OR SELENIZATION IN MOLTEN (LIQUID) STATE FOR THE PHOTOVOLTAIC APPLICATIONS

(75) Inventors: Kaushal K. Singh, Santa Clara, CA (US); Ralf Hofmann, Soquel, CA (US); Nety M. Krishna, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/755,203

(22) Filed: Apr. 6, 2010

Related U.S. Application Data
(60) Provisional application No. 61/167,449, filed on Apr. 7, 2009.

(51) Int. Cl. H01L 21/363

(52) U.S. Cl. 438/478; 257/E21.462

(57) ABSTRACT

A method of forming a solar cell incorporating a compound semiconductor is provided. The compound semiconductor is generally of the “II/VI” variety, and is formed by depositing one or more group II elements in a vapor deposition process, and then contacting the deposited layer with a liquid bath of the group VI elements. The liquid bath may comprise a pure element or a mixture of elements. The contacting is performed under a non-reactive atmosphere, or vacuum, and any fugitive vapors may be captured by a cold trap and recycled. The substrate may be subsequently annealed to remove any excess of the group VI elements, which may be similarly recycled.

### CROSS-REFERENCE TO RELATED APPLICATIONS

This application claims benefit of U.S. Provisional Patent Application Ser. No. 61/167,449 filed Apr. 7, 2009, which is herein incorporated by reference.

### BACKGROUND OF THE INVENTION

1. Field of the Invention

Embodiments of the invention relate to formation of compound semiconductor materials. More specifically, embodiments of the invention relate to methods of forming compound semiconductors having a group VI element.

2. Description of the Related Art

Increasing focus on renewable sources of energy have led to development of many types of solar cells involving semiconductors as energy absorbers. Although silicon-based solar cells are the most common, one increasingly common type of semiconductor used in thin film solar cells is the compound semiconductor. Compound materials formed from so-called “II/VI” mixtures generally have semiconducting properties useful for solar cell energy absorber layers. Examples of such materials include copper indium gallium sulfide or selenide (CulnGa(S,Se)₂, “CIGS”), cadmium sulfide (CdS), mercury cadmium telluride (HgCdTe), and cadmium telluride (CdTe). Materials in this category are generally made from one or more elements from chemical groups 11-13, sometimes referred to as group II elements (not to be confused with group 2, alkaline earth, elements), and one or more elements from chemical group 16, sometimes referred to as group VI elements. The group II elements most commonly found in II/VI semiconductors are Cu, Zn, Cd, Hg, Ga, and In, although Al and Tl are also occasionally used. The group VI elements most commonly used are S, Se, and Te.

The group II elements are generally deposited on a substrate in a layer and then infused with the group VI elements. A contact layer may be formed on the substrate prior to depositing the group II elements. In conventional processes, all steps are vapor deposition steps. In particular, the process of infusing the group VI elements generally involves exposing the substrate to a vapor containing the elements to be incorporated into the substrate. Commonly, sulfur or selenium is vaporized or provided as a gaseous compound such as H₂S, H₂Se or low-boiling organosulfur or organoselenium compounds (e.g. diethylselenide). In some processes, H₂S or H₂Se are formed in-situ by vaporizing sulfur or selenium in a hydrogen atmosphere. These sulfur and/or selenium species are provided to a chamber in excess and contacted with the substrate under pressure to accomplish the selenization or sulfurization.

Compounds used today in sulfurization and selenization processes are hazardous. Hydrogen selenide is quite toxic, and both hydrogen selenide and hydrogen sulfide can degrade process equipment, and may be incompatible with some substrate materials. Additionally, vapor exposure processes have high material utilization rates, because most of the vapor is not incorporated into the substrate. Also, solar cells formed using vapor techniques frequently have reduced performance characteristics due to high defect densities and incorporation of hydrogen. Processes developed to address the performance issues, such as thermal co-evaporation, are inefficient due to low throughput and high material utilization.

Thus, there is a continuing need for an effective, efficient process for manufacturing solar panels or cells incorporating compound semiconductors.

### SUMMARY OF THE INVENTION

Embodiments of the invention provide a method of processing a substrate, comprising depositing a first substance on the substrate by a physical vapor deposition process, incorporating a second substrate into the first substance by exposing the first substance to a liquid comprising the second substance, and diffusing the second substance into the first substance.

Other embodiments provide a method of forming a layer on a substrate, comprising sputtering one or more metal layers onto a surface of the substrate, contacting the one or more metal layers with a liquid comprising one or more group VI elements, diffusing the one or more group VI elements into the one or more metal layers, and annealing the substrate.

Further embodiments provide a method of forming a compound semiconductor, comprising depositing a molybdenum layer on a substrate by physical vapor deposition, depositing a copper-indium-gallium alloy layer on the molybdenum layer by physical vapor deposition, heating the substrate to a temperature of at least 400° C., contacting the copper-indium-gallium alloy layer with liquid bath comprising one or more group VI elements, diffusing an excess amount of the one or more group VI elements into the copper-indium-gallium alloy layer and reacting the one or more group VI elements with the copper-indium-gallium alloy layer, and reducing the excess of group VI elements by volatilizing the excess group VI elements in an annealing process.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram summarizing a method according to one embodiment.

FIG. 2 is a flow diagram summarizing a method according to another embodiment.

FIG. 3 is a plan view of an apparatus according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally provide a method of incorporating a chemical component into a solar cell substrate. Methods described herein are generally useful for fabricating so-called II/VI compound semiconductors, which have uses in solar panel and integrated circuit applications. Compounds in this group generally comprise components selected from the group consisting of copper, indium, gallium, molybdenum, thallium, zinc, mercury, boron, aluminum, silver, sulfur, selenium, and tellurium. In solar and I/C applications, these compounds are generally formed on a substrate as thin films having near-stoichiometric quantities of the “group II” components (Cu, In, Ga, TI, Zn, Hg, B, Al, Ag) with one or more of the “group VI” components (S, Se, Te). While metals in the zinc column of the periodic table are frequently used alone as the group II component (e.g. CdS, CdSe), elements on one side of the zinc column are frequently combined with elements on the other side to provide the group II component (e.g. CuInGaS).

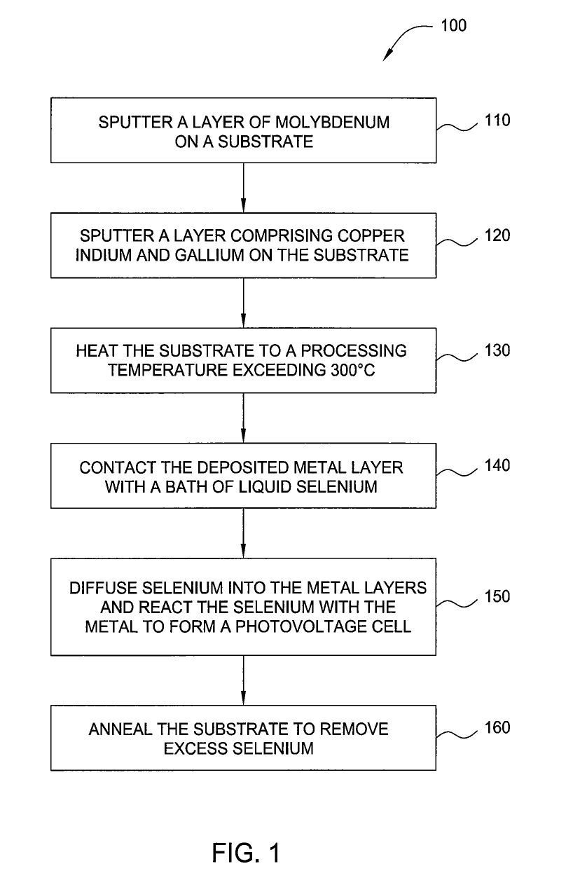

FIG. 1 is a flow diagram summarizing a method 100 according to one embodiment. In the embodiment of FIG. 1, a CIGS solar cell is formed on a substrate. At 110, a layer of molybdenum is deposited on the substrate in a PVD process, as is known in the art. The molybdenum layer serves as the back contact for the solar cell, and may be up to about 5 μm thick in most embodiments. At 120, copper, indium, and gallium (CIG) are deposited in a CIG absorber layer on the substrate using one composite sputtering target or multiple targets of pure materials. The CIG layer may be up to about 1 μm thick in most embodiments. Selenium is next incorporated into the CIG layer by contacting the CIG layer with liquid selenium.

Substrates generally useful for the methods described herein include glass substrates such as borosilicate glass, phosphosilicate glass, and soda lime glass, quartz, various spinels such as sapphire or gallium/indium/aluminum nitrides, or metals.

At 130 the substrate is heated to a processing temperature exceeding 300° C. Heating the substrate ensures the liquid selenium does not freeze on the substrate surface, promotes diffusion of liquid selenium into the CIG layer, and promotes reaction of the selenium with the CIG components to produce the compound semiconductor. The substrate may be heated in a separate apparatus from the selenization apparatus, such as a thermal chamber or heated transport apparatus, and may be advantageously heated to a temperature below a softening point of the substrate. In some embodiments, the substrate may be heated to a temperature between about 225° C. and about 550° C., such as between about 300° C. and about 500° C., for example about 450° C. Not wishing to be bound by theory, it is believed that heating the substrate increases the number and size of diffusion pathways for liquid selenium into layers of the substrate. Heating the substrate may also improve adhesion of layers previously deposited on the substrate.

At 140, the metal layers deposited above are contacted with a bath of liquid selenium. The liquid selenium may be maintained in a heated receptacle and provided to a contact point for contacting with the substrate. The liquid may be contacted with the substrate by pouring the liquid over the substrate or by dipping the substrate surface in the liquid. In one embodiment, the liquid may be made to flow over an obstacle, like an upright weir, to create a contact point, and the substrate passed over the end of the upright weir to contact the liquid. In another embodiment, the liquid may be made to flow over the edge of a horizontally-extending barrier, and the substrate passed near the end of the barrier to contact the liquid. In another embodiment, the liquid may be made to flow through a die or slit, which may be heated, onto a substrate passing beneath the die or slit. In another embodiment, the liquid may be spray-coated, roller-coated, or die-coated onto a substrate.

In one embodiment, a substrate is positioned at a processing station, and liquid selenium dispensed onto the surface of the substrate. In another embodiment, a substrate passes through a processing station on a moving conveyor as liquid selenium is dispensed onto the substrate surface.

In many embodiments, shear forces on the liquid selenium are minimized to maximize diffusion of selenium into the substrate. Wishing not to be bound by theory, it is believed that shear forces generate lateral movement of selenium atoms and molecules parallel to the substrate surface, slowing diffusion into the surface. In many embodiments, diffusion into the substrate is facilitated by good wetting of the substrate surface. The combination of surface wetting factor and surface roughness influences the rate of mass diffusion, which depends linearly on both to a fair approximation within certain ranges. At high values of surface roughness, diffusion rate no longer increases with increasing roughness, and may actually decline due to inability to wet the surface effectively.

At 150, the liquid selenium is encouraged to diffuse into the metal layers and react therewith to form a photovoltaic cell. Each area of the substrate in which selenium is to be incorporated is exposed to the liquid selenium bath for a time from about 2 minutes to about 10 minutes. The time required depends on the temperature of the exposure, the higher temperature encouraging diffusion rate and reaction rate of selenium with the deposited metals. A high exposure temperature may also result in loss of some components from the deposited metal alloy, depending on the composition thereof. Indium and gallium melt at 156.6° C. and 29.8° C., respectively, and may be locally freed from the metal matrix at high temperatures. Modifications of the metal layer during selenization may have effects on the eventual properties of the formed semiconductor such as band gap and voltage. In some embodiments, an exposure temperature between about 400° C. and about 500° C. for 2-3 minutes results in penetration of selenium to a depth of about 2 mm. In some embodiments, a slightly longer exposure, such as between about 4-6 minutes, at a temperature between about 350° C. and about 450° C. results in more uniform compositional distribution of selenium in the formed semiconductor. In some embodiments, the resulting composition comprises at least about 50 atomic percent selenium, such as between about 50 atomic percent and 75 atomic percent, for example between about 55 atomic percent and about 60 atomic percent.

Exposure to liquid selenium is performed under a non-reactive atmosphere. Low pressure, non-reactive components, or a combination thereof, may be employed to prevent reaction of components in the vapor phase with the liquid selenium or the substrate. Non-reactive gases that may be used include nitrogen, argon, helium, and neon. In some embodiments, liquid exposure may be performed under vacuum at pressures between about 1 mTorr and 100 Torr with a nominal flow of inert gas above the contact area, such as between about 100 sccm and about 2,000 sccm.

At 160, the substrate is annealed to remove excess selenium and improve the compositional uniformity and grain size of the formed semiconductor. As mentioned above, a slower exposure may partially complete the anneal process. Annealing may be performed in a thermal treatment chamber configured in-line with the liquid exposure chamber such that there is no intermediate cooling of the substrate prior to annealing, or the substrate may be annealed after a brief cooling period. The substrate is generally annealed at a temperature between about 200° C. and about 550° C. for about 5 minutes to about 60 minutes. In one embodiment, the substrate is annealed at a temperature between about 400° C. and about 500° C. In another embodiment, the substrate is annealed between about 5 minutes and about 20 minutes. In some embodiments, a brief cool-down may be used to engineer the thermal history of the formed semiconductor to produce compositional or morphological gradients therein. For example, following a rapid diffusion process, the substrate may be rapidly cooled below about 100° C. for about 30 seconds or less to form crystal grains, and then the substrate may be annealed by applying directional heat, such as back-side heat or front-side heat, to dissolve at least a portion of the crystal grains starting at one surface of the substrate and proceeding to the other.

During annealing, any excess unreacted selenium absorbed into the substrate during selenization may be eliminated. In some embodiments, a layer rich in selenium near the surface of the substrate may release selenium in a volatile state. Because selenium vaporizes at 685° C. at atmospheric pressure, a low-pressure or vacuum anneal may be helpful in removing excess selenium. The selenium vapors are collected in a cold trap operating near ambient temperature with a liquid or vapor coolant, and the recovered selenium may be recycled to the liquid bath. In this way, no selenium is wasted, and utilization of material to make CIGS solar cells is low.

Use of liquid selenium under a non-reactive atmosphere to incorporate selenium into a CIG layer avoids the need to use toxic and potentially corrosive gases. Gases such as H₂Se, commonly used in current selenization processes suffer from poor utilization because most of the gas does not contribute to the semiconductor, and it mostly cannot be recycled due to reactions with process components that contaminate the gas. Liquid selenium under an inert atmosphere generally does not corrode or degrade process equipment, and the option to capture and recycle excess selenium results in excellent material utilization and low cost. The methods described above may be used to incorporate group VI components other than selenium into a substrate, as is further described below.

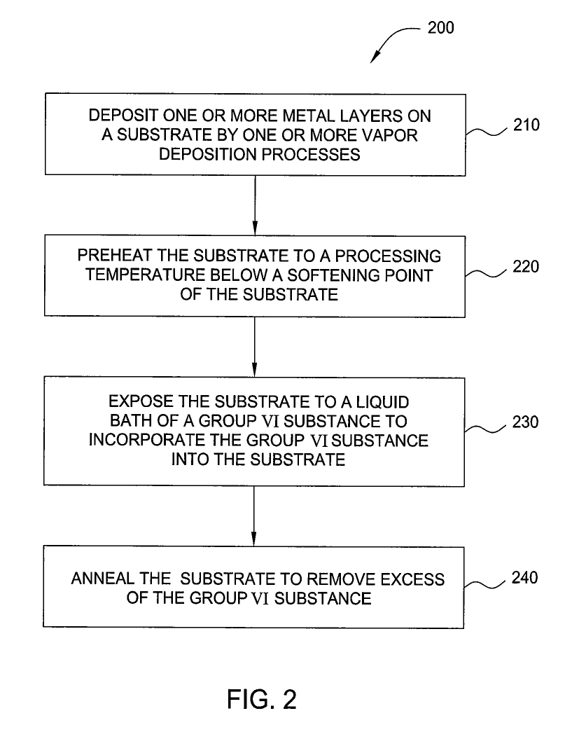

Methods described herein may be used to incorporate any group VI component into a substrate. FIG. 2 is a flow diagram that summarizes a method 200 according to another embodiment. At 210, one or more materials are deposited on a substrate by one or more vapor deposition processes, such as PVD. The materials deposited are generally desirous of incorporating a group VI component to form a compound semiconductor. Such materials may include alkaline earth or transition metals, and may include alloys, mixtures, or combinations of such metals. Some elements that may be combined with group VI elements to form compound semiconductors using methods embodying the invention include copper, indium, gallium, molybdenum, thallium, zinc, mercury, boron, aluminum, and silver. The group VI elements that may be incorporated according to embodiments include sulfur, selenium, and tellurium.

At 210, a layer to be infused with one or more group VI elements is formed on a substrate by a vapor deposition process. In many embodiments, the layer will be metal and may be a metal alloy. The metals listed above are frequently combined with group VI elements. The one or more metals may be deposited by physical or chemical vapor deposition, which may be plasma enhanced. In one embodiment, the metals may be deposited by sputtering, wherein the sputtering targets are pure metals. In one embodiment, a first metal is deposited by sputtering to form a first metal layer, and a second metal is deposited by sputtering to form a second metal layer over the first metal layer. The first and second metal layers may each be pure metals or alloys of two or more metals. In one example, the first metal layer is molybdenum and the second metal layer is an alloy of copper, indium, and gallium. In another example, a metal layer is deposited using two sputtering targets having different compositions to form an alloy layer. In another example, a metal layer having a desired composition is deposited using one or more sputtering targets having the desired composition.

In most embodiments, the layer or layers deposited at 210 will have an overall thickness between about 100 nm and about 5 μm. In one embodiment, the layer deposited at 210 comprises a first layer and a second layer, wherein the first layer is a contact layer and the second layer is the metal component of an absorber layer. In such an embodiment, the second layer may be thicker than the first layer. For example, a contact layer may be between about 100 Å and about 1,000 Å, and the metal component of the absorber layer may be between about 2,000 Å and about 2 mm thick.

At 220, the substrate is preheated to a processing temperature selected to facilitate incorporation of the group VI elements. The processing temperature is generally less than a softening point of the substrate. In many embodiments, the processing temperature is less than about 550° C., such as between about 120° C. and about 550° C., or between about 225° C. and about 550° C., or between about 350° C. and about 500° C. In an embodiment wherein sulfur alone is to be incorporated into the substrate, the processing temperature may be between about 120° C. and about 550° C. In an embodiment wherein selenium alone is to be incorporated into the substrate, the processing temperature may be between about 225° C. and about 550° C. In an embodiment wherein tellurium alone is to be incorporated into the substrate, the processing temperature may be between about 450° C. and about 550° C.

Not wishing to be bound by theory, it is believed that preheating the substrate to a processing temperature increases the number and size of diffusion pathways into layers of the substrate. Heating the substrate may also improve adhesion of layers previously deposited on the substrate.

At 230, the substrate is exposed to a liquid bath of a group VI substance. The group VI substance may be sulfur, selenium, tellurium, or any combination thereof. The substrate may be exposed to the liquid by dipping, or by flowing the liquid across the substrate surface as described above in connection with FIG. 1. The substrate is exposed to the liquid for a time sufficient to incorporate the group VI substance into the substrate to form a compound semiconductor. The exposure time may be from about 5 minutes to about 60 minutes depending on the embodiment. A higher temperature exposure will take less time, so exposures at higher temperatures may only require exposure for about 5 minutes to about 15 minutes, while lower temperatures may require exposure for about 45 minutes to about 60 minutes. Higher temperatures speed the rate of diffusion into the substrate and the rate of reaction with materials already deposited on the substrate, but very high temperatures may risk loss of material from layers already deposited on the substrate, altering the properties of the resulting compound layer. Short diffusion times at higher temperatures may also result in less uniform composition of the resulting material.

As described in connection with FIG. 1, diffusion rates may be influenced by roughness, wettability, and shear forces in the manner of contact between the substrate and the liquid. A higher temperature will reduce surface energy of the liquid, improving wetting of rough substrates. Presence of higher molecular weight species will directionally increase surface energy of the liquid.

Exposure to the liquid bath is performed under a non-reactive atmosphere. Low pressure, non-reactive components, or a combination thereof may be employed to prevent reaction of components in the vapor phase with the liquid phase or the substrate. Non-reactive gases that may be used include nitrogen, argon, helium, and neon. In some embodiments, liquid exposure may be performed under vacuum at pressures between about 1 mTorr and 100 Torr with a nominal flow of inert gas above the contact area, such as between about 100 sccm and about 2,000 sccm. In some embodiments, fugitive vapor from the liquid bath may be recovered by passing effluent gas from the chamber through a recovery apparatus, such as a cold trap, and recycling the recovered liquid to the bath. The cold trap may be a jacketed vessel operated at ambient temperature by passing water or air through the jacket.

At 240, the substrate is annealed to remove any excess group VI elements. The annealing is generally performed under a non-reactive atmosphere at a temperature below a softening temperature of the substrate. Annealing may be performed in a thermal treatment chamber configured in-line with the liquid bath chamber such that there is no intermediate cooling of the substrate prior to annealing, or the substrate may be annealed after a brief cooling period. The substrate is generally annealed at a temperature between about 200° C. and about 550° C. for about 5 minutes to about 60 minutes. In one embodiment, the substrate is annealed at a temperature between about 400° C. and about 500° C. In another embodiment, the substrate is annealed between about 5 minutes and about 20 minutes. Annealing time, temperature, and pressure are adjusted depending on the species to be removed. Higher-boiling species such as tellurium may require annealing at higher temperature, lower pressure, and/or longer time to fully anneal.

In some embodiments, a longer exposure to the liquid bath at an elevated temperature may enable a shorter anneal time. The exposure time may be extended to partially anneal the substrate in the presence of the liquid bath to ensure full saturation of the substrate with the group VI species. In most embodiments, the group VI elements will be incorporated in the substrate to a level of at least 50 atomic percent, such as between about 50 atomic percent and about 75 atomic percent, or between about 50 atomic percent and about 60 atomic percent, such as at least about 55 atomic percent. Annealing the substrate reduces the concentration of group VI elements in the layer by volatilizing excess group VI elements from the substrate. The substrate is generally annealed until the concentration of group VI elements reaches a target amount.

Annealing the substrate also stabilizes the composition of the layer formed on the substrate. Compositional uniformity is improved by diffusion of group VI species through the layer, and excess is removed as vapor. The excess may be condensed in a cold trap using a cooling fluid such as air or water as the cooling medium, and the condensed material recycled to the liquid bath to ensure efficient utilization of raw materials.

In some embodiments, a substrate processed according to methods described herein may be subjected to one or more annealing processes that comprise more than one heating cycle. In some embodiments, an annealing process comprising more than one heating cycle may be more effective than a single heating cycle. For example, in one embodiment, a first anneal may subject a substrate to heat soaking at a first temperature, and a second anneal may subject the substrate to heat soaking at a second temperature, with a cooling cycle between the first anneal and the second anneal. The first anneal may successfully remove most of the excess material deposited on and incorporated into portions of the substrate near the surface, and the second anneal may be needed to remove excess incorporated more deeply in the substrate. The first anneal may create a local deficit of group VI species near the surface of the substrate, which is refilled by diffusion from lower layers of the substrate during the cooling cycle. The second anneal may then remove any remaining excess from the substrate. The first and second temperatures may be the same or different, with the second temperature higher or lower, depending on the embodiment.

In some embodiments, a brief cool-down may be used to engineer the thermal history of the formed semiconductor to produce compositional or morphological gradients therein. For example, following a rapid diffusion process, the substrate may be rapidly cooled below about 100° C. for about 30 seconds or less to form crystal grains, and then the substrate may be annealed by applying directional heat, such as back-side heat or front-side heat, to dissolve at least a portion of the crystal grains from one surface of the substrate to the other.

In other embodiments, annealing may be accomplished by subjecting the substrate to a programmed heat history. In one embodiment, the temperature of the substrate may be ramped to a first temperature at a first rate. The substrate may be maintained at the first temperature for a first soak time. The substrate temperature may then be ramped up to a second temperature at a second rate, and then maintained at the second temperature for a second soak time. A programmed heat history may be more effective in annealing the substrate in some embodiments by increasing the volatility of unincorporated group VI elements as the concentration thereof declines. Initially, the excess of group VI elements will be relatively large, and most will be removed by the first soak. The increased temperature of the second soak will then increase the volatility of the remaining excess to ensure the concentration of group VI elements reaches the target level.

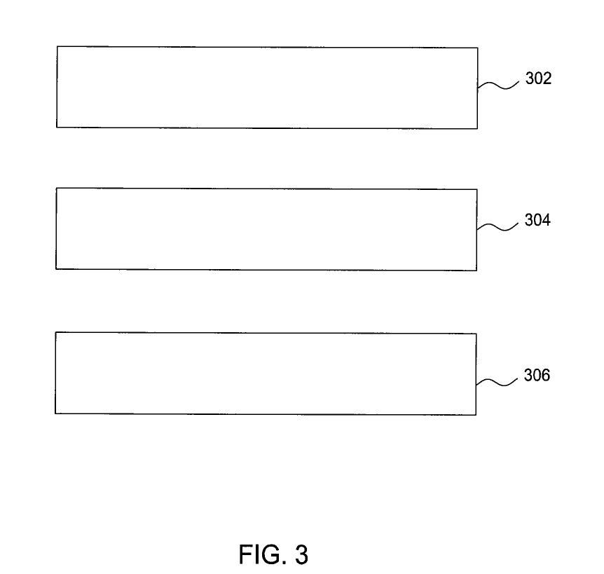

FIG. 3 is a schematic plan view of an apparatus according to another embodiment. The schematic apparatus of FIG. 3 is configured to perform the methods described herein. The apparatus of FIG. 3 comprises a metal deposition station 302, which may be a CVD or PVD chamber or a liquid deposition chamber such as an electrochemical or electroless deposition chamber. A substrate is disposed in the metal deposition station 302 for deposition of a metal layer thereon. The metal layer is generally a group II metal, as described elsewhere herein, and forms a component of a compound semiconductor to be formed on the substrate.

The apparatus of FIG. 3 also comprises a liquid exposure station 304. A substrate is disposed in the liquid exposure station 304 for exposing the group II metal layer to a liquid group VI component, as described herein above. The liquid maybe contacted with the substrate through dipping, either of the entire substrate or just the surface to be contacted, spray coating, spin coating, roller coating, die coating, ribbon coating, weir overflow coating, or waterfall coating, as described herein above. The liquid layer is generally applied in a thin layer that remains on the substrate surface as the substrate is moved to the anneal chamber.

The apparatus of FIG. 3 also comprises an anneal station 306 for thermally treating the substrate having a group II metal layer with a group VI liquid component diffused therein. The substrate may be transported from the metal deposition station 302 to the liquid exposure station 304 and to the anneal station 306 by a substrate transport apparatus (not shown in the schematic plan view of FIG. 3), which may be a conveyor system. Each of the stations 302, 304, and 306 may comprise a chamber for a controlled processing environment, or one or more of the stations 302, 304, and 306 may be collectively enclosed in a single processing environment or chamber.

While the foregoing is directed to embodiments of the invention, other and further embodiments of the invention may be devised without departing from the basic scope thereof.

What is claimed is:

1. A method of processing a substrate, comprising:
depositing a first substance on the substrate by a physical vapor deposition process;
incorporating a second substance into the first substance by exposing the first substance to a liquid comprising the second substance; and
diffusing the second substance into the first substance.

2. The method of claim 1, wherein the first substance is metal, and the second substance is non-metal.

3. The method of claim 1, wherein the second substance has a melting point below a softening temperature of the substrate.

4. The method of claim 1, wherein the first substance comprises one or more elements from the group consisting of copper, indium, gallium, molybdenum, thallium, zinc, mixtures thereof, combinations thereof, and alloys thereof.

5. The method of claim 1, wherein the second substance is selected from the group consisting of sulfur, selenium, tellurium, gallium, indium, thallium, thallium selenide, selenium sulfide, diselenium hexasulfide, mixtures thereof, combinations thereof, and alloys thereof.

6. The method of claim 1, wherein the first substance comprises a plurality of metal layers.

7. The method of claim 1, wherein the first substance comprises a plurality of layers of one or more elements selected from the group consisting of copper, indium, gallium, molybdenum, thallium, zinc, mixtures thereof, combinations thereof, and alloys thereof, and the second substance is selected from the group consisting of sulfur selenium, tellurium, gallium, indium, thallium, thallium selenide, selenium sulfide, diselenium hexasulfide, mixtures thereof, combinations thereof, and alloys thereof.

8. The method of claim 1, further comprising removing any excess quantity of the second substance from the substrate by annealing the substrate.

9. A method of forming a layer on a substrate, comprising:
sputtering one or more metal layers onto a surface of the substrate;
contacting the one or more metal layers with a liquid comprising one or more group VI elements;
diffusing the one or more group VI elements into the one or more metal layers; and
annealing the substrate.

10. The method of claim 9, wherein the one or more metal layers comprise an element from the group consisting of cadmium, copper, indium, gallium, zinc, nickel, aluminum, mixtures thereof, combinations thereof, or alloys thereof.

11. The method of claim 9, wherein contacting the one or more metal layers with a liquid comprising one or more group VI elements comprises wetting the metal layer with one or more elements from the group consisting of sulfur, selenium, thallium, indium, tellurium, mixtures thereof, compounds thereof, combinations thereof, or alloys thereof.

12. The method of claim 9, wherein diffusing the one or more group VI elements into the one or more metal layers comprises heating the substrate to a temperature between the melting points of the one or more group VI elements and a softening point of the substrate.

13. The method of claim 9, further comprising maintaining a non-reactive atmosphere above the substrate while contacting the one or more metal layers with the liquid and diffusing the one or more group VI elements into the one or more metal layers.

14. The method of claim 9, wherein annealing the substrate comprises volatilizing excess quantities of the one or more group VI elements diffused into the substrate, and condensing the volatile group VI elements in a cold trap.

15. The method of claim 9, wherein annealing the substrate comprises exposing the substrate to a programmed heat history comprising at least two different temperatures.

16. A method of forming a compound semiconductor, comprising:
depositing a molybdenum layer on a substrate by physical vapor deposition;
depositing a copper-indium-gallium alloy layer on the molybdenum layer by physical vapor deposition;
heating the substrate to a temperature of at least about 400° C.;
contacting the copper-indium-gallium alloy layer with a liquid bath comprising one or more group VI elements;
diffusing an excess amount of the one or more group VI elements into the copper-indium-gallium alloy layer and reacting the one or more group VI elements with the copper-indium-gallium alloy layer; and
reducing the excess of group VI elements by volatilizing the excess group VI elements in an annealing process.

17. The method of claim 16, wherein the group VI elements are selected from the group consisting of sulfur, selenium, and tellurium.

18. The method of claim 16, wherein the liquid bath comprises one or more substances selected from the group consisting of sulfur, selenium, tellurium, gallium, indium, thallium, thallium selenide, selenium sulfide, diselenium hexasulfide, mixtures thereof, combinations thereof, and alloys thereof.

19. The method of claim 16, wherein the annealing process comprises subjecting the substrate to a programmed heat history.

20. The method of claim 19, wherein the programmed heat history comprises heat soaking the substrate at two or more different temperatures.
